(19) United States
(12) Patent Application Publication
(10) Pub. No.: US 2007/0072393 A1
(43) Pub. Date: Mar. 29, 2007

(54) Method for preparing and assembling substrates

(75) Inventors: Bernard Aspar, Rives (FR); Chrystelle Lagahe-Blanchard, St. Joseph De Riviere (FR)

Correspondence Address: OBLON, SPIVAK, MCCLELLAND, MAIER & NEUSTADT, P.C., 1940 DUKE STREET, ALEXANDRIA, VA, 22314, US

(73) Assignee: TRACIT TECHNOLOGIES, Moirans (FR)

(21) Appl. No.: 10/574,798

(22) PCT Filed: Oct. 14, 2004
(86) PCT No.: PCT/EP04/52548

§ 371 Date: Dec. 11, 2006

Related U.S. Application Data
(60) Provisional application No. 60/568,700, filed on May 7, 2004.

(30) Foreign Application Priority Data
Oct. 14, 2003 (FR) 03/50674

(51) Int. Cl. H01L 21/30; H01L 21/00; H01L 21/46

(52) U.S. Cl. 438/459; 438/460; 438/462

(57) ABSTRACT

A method for assembling a first and a second wafer of material, including routing at least the first wafer and assembling the first and second wafer.

### TECHNICAL FIELD AND PRIOR ART

The invention relates to the field of assembling wafers or slices or layers of material, notably semiconductors, and of their preparation with the purpose of assembling them.

Among the assembly techniques of such substrates, molecular adhesion allows to assemble flat structures of low surface roughness.

It allows to obtain unique structures and is particularly well adapted for bonding together wafers of material used in microelectronics, such as, for example, wafers in silicon, or III-V material (AsGa, InP) or glass or fused silica or vitreous fused silica glass substrates.

Nowadays this technique is used industrially, for example in the manufacture of SOI (Silicon On Insulator) material.

The known methods for manufacturing SOI material, which use molecular adhesion, implement two wafers 2, 4 of silicon (FIG. 1, part A), of which at least one of the two has a layer 6 of oxide on the surface.

These two wafers are of standard size. The edges 5 and 7 are generally chamfered, so as to avoid fractures likely to appear during eventual manufacturing of components or in the event of shocks to still sharp edges. There are rounded and/or bevelled chamfers. FIG. 2 represents, in greater detail, an example of a chamfer zone 5, of width L (measured on a plane parallel to the mean plane P of the wafer) of a wafer 4, of thickness e.

The assembling firstly comprises a surface preparation stage, a putting together stage (FIG. 1, part B), generally followed by a heat treatment stage.

Normally, this heat treatment is performed at 1100° C. for 2 hours for SOI substrates.

Then, as illustrated in FIG. 1, part C, at least one of the two wafers is thinned out via surface edge grinding and/or mechanical polishing and/or mechano-chemical polishing.

The chamfers 5 and 7 generate the existence of a non-bonded zone on the wafer edges.

After thinning out, a membrane 8 made in silicon remains bonded to the centre, but detached on the edges, as visible in FIG. 1, part C.

The detached edge of the membrane must be removed, as it is likely to break in an uncontrolled manner and introduce particles on the other surfaces, and notably on surface 9 of the membrane 8, or on components made in the membrane 8.

For this reason a stage for routing or eliminating matter in the peripheral zone is performed in order to eliminate this edge zone from the membrane 8, as illustrated in FIG. 1, part D.

This routing is normally performed via mechanical means.

This stage is very delicate. For example, in the event of mechanical machining, it is difficult to route or trim everything and to stop exactly at the bonding interface, which in this case is the upper surface of the oxide layer 6. Indeed, either we stop just above this interface leaving some matter above the latter, or we stop in the support 2 and the surface polish of the edges of the front face of the support is lost.

It is therefore important to find a means of properly and accurately routing or trimming a wafer of material.

This phenomenon is also important in the case where at least one of the two wafers contains all or part of an electronic or opto-electronic device, or a micro-system, or a nano-system or another component.

The same problem exists if the assembling of the two wafers is done via bonding instead of molecular adhesion, or even without the oxide layer 6 on the surface of the wafer 12.

Another problem is the marking of one or both of the two wafers 2 and 4, generally on the support wafer, with the purpose of providing specific information such as for example identification information of a batch. For example, on SOI wafers, due to their multilayer nature, a marking, generally via etching, induces a greater number of particles than on bulk wafers.

### PRESENTATION OF THE INVENTION

The invention firstly relates to a method for assembling a first and a second wafer of material, comprising:

a routing or trimming stage of at least the first wafer;

an assembling stage of at least the first wafer, routed or trimmed, and of the second wafer.

According to the invention, a machining, or routing or eliminating or trimming stage of the matter in a peripheral section of at least the first wafer, is thus performed before bonding or assembling the two wafers together.

A thinning out stage of at least the first wafer can then be carried out, leaving a layer on the second wafer. A transplanting or transferring of this layer is thus achieved.

The invention also relates to a method for transplanting or transferring a layer of material, circuits or components, known as transplant or transfer layer, comprising:

the routing or trimming of a first wafer of material, or the elimination of matter in a peripheral section of a first wafer, in which the transplant layer or the layer to transfer is made, at least in a zone located around or on the periphery of this transplant layer;

the transplanting or transferring of this layer onto a second wafer of material.

This transplanting or transferring is performed via assembling the first and second wafers and then thinning out the first wafer.

The first wafer of the method for assembling, transplanting or transferring is for example a chamfered wafer, bearing at least one chamfered edge. The routing or trimming thus relates to at least a part of the chamfered edge. It can also eat into a part, normally peripheral, of the transplant or transfer layer.

The method for assembling or transplanting according to the invention thus allows to obtain a structure with a first wafer, possibly chamfered, perfectly routed before assembling, the routing or trimming being devoid of the problems developed above in the context of the prior art, problems due to the existence of a second wafer.

It can apply as much to wafers containing all or part of an electronic component or other, as to blank wafers, such as wafers known as “bulk”.

Routing or trimming stages before assembling can be performed before or after possible surface preparation stages with the purpose of assembling or transplanting.

The first wafer can be routed or trimmed through its entire thickness, or through its lesser thickness, for example equal to or greater than the final thickness of the layer that is sought after or transplanted onto the second wafer.

According to an alternative, the routing or trimming can also be performed over a thickness that is less than this final thickness.

In this case, it could be beneficial to end the routing, in a standard manner, after assembling, with one or other of the two faces of the first wafer.

If the substrates or wafers have comparable initial dimensions or initial diameters, the thickness of the routing or trimming can be such that the routed wafer has, after routing or trimming, a dimension or diameter less than the other wafer.

Preferably, in the case where the first wafer has a rollover edge or chamfer, the width, measured on the plane of the wafer, on which the upper wafer is routed or trimmed, is greater than or equal to the width of the rollover or chamfer.

It can also have a width greater than or equal to the width of the zone which can not be bonded or assembled due to the rollover or chamfer.

The first wafer can have a zone or a weakened or cleavage or fracture plane, created in depth for example by hydrogen implantation or by the creation of a buried porous zone or by the creation of a removable bonding interface.

When the thickness of the routed zone is greater than the thickness of the desired thin layer, this routed wafer can be recycled, without the need of routing before bonding onto a new substrate. A new weakened a cleavage or fracture plane can thus be created, then it can be directly assembled with a new substrate.

The assembling of the two wafers can be performed via molecular adhesion or via bonding, through the adding of matter such as for example adhesive or wax.

The routing or trimming stage can be performed in a regular manner around the first wafer.

It can also be performed in an irregular manner around the first wafer, creating one or more flats or flat surfaces.

The routing or trimming stage can also be performed in an irregular manner, creating at least one marking zone in at least one of the wafers. A marking stage in at least one of these marking zones can then be carried out.

According to another aspect, the object of the invention is also a method for assembling a first and a second wafer of material, comprising:

an assembling stage of the first wafer and of the second wafer;

a routing or trimming stage of at least the first and/or the second wafer and the creating of at least a marking zone and/or at least an irregular zone on the periphery of the first and/or the second wafer.

One of the wafers, for example the first, can have at least one chamfered edge.

The invention thus allows to make a specific zone, for example with the purpose of marking a wafer, whether the routing or trimming takes place before or after the assembling of the wafers.

When routing or trimming takes place after assembling, a thinning out stage of one of the two wafers can take place before or after routing or trimming, leaving at least one layer on the other wafer.

When routing takes place after assembling, the process can comprise one or several of the following characteristics or stages:

the routing or trimming can take place over the entire thickness of the routed wafer;

and/or at least one of the two wafers can be processed, that meaning have components or circuits;

and/or the routing or trimming stage is performed over a width Ld, measured on a plane parallel to that of the first wafer, of between 100 μm and 5 mm;

and/or the first or the second wafer can be chamfered, and have at least one chamfered edge;

and/or the routing or trimming stage can be performed over a width Ld, measured on a plane parallel to that of the first wafer, at least equal to the width L of the chamfered edge, measured on the same plane;

and/or the assembling of the two substrates can be performed via molecular adhesion or via bonding using an adhesive substance;

and/or the routing or trimming can be performed via mechanical, chemical or mechano-chemical etching or via plasma etching or via a combination of at least two of these types of etching;

and/or at least one of the two wafers can be made in a semiconductor material, for example in silicon or in a III-V type semiconductor material;

and/or at least one of the two wafers can be made in Germanium or in Germanium silicon or in a piezoelectric material or in an insulating material.

### BRIEF DESCRIPTION OF THE FIGURES

FIG. 1, parts A-D, represents stages of a known method for assembling substrates.

FIG. 2 represents a part of a substrate and its edge or rollover edge.

FIG. 3, parts A-D, represents stages of a method according to the invention.

FIGS. 4, parts A-C, and 5, parts A-B, represent an alternative of a method according to the invention.

FIG. 6, parts A-E, represents an alternative of a method according to the invention, in the case of a substrate with a weakened plane.

FIG. 7, parts A-D, represents an alternative of a method according to the invention, in the case of a substrate with a protective or bonding layer.

FIGS. 8A-8D represent a front view of the routed or trimmed wafers.

FIG. 9 represents a wafer of material with a lateral shoulder.

FIGS. 10A-10B represent a wafer with an embedding.

### EXAMPLES OF EMBODIMENTS OF THE INVENTION

FIG. 3, parts A-D, represents stages of a method according to the invention.

Two wafers 12 and 14 are chosen, for example two wafers of semiconductor material, such as standard silicon wafers.

These wafers can typically have a thickness of between 300 μm and 800 μm. They are for example wafers of 100 mm or 200 mm or 300 mm in diameter.

For the aforementioned reasons, the edges 15 and 17 are chamfered.

Components or circuits 16 may have previously been made in the wafer 12, but the invention also relates to the case of a wafer 12 absent of any circuit, the reference 16 thus designating a layer of material to be transplanted or transferred onto the wafer 14. In FIG. 3, part B, the surface of this layer 16 of circuits or material to be transplanted or transferred lies flush with the surface of the wafer 12.

A routing or matter eliminating or trimming stage is then performed (FIG. 3, part B), starting from the face 19 of the wafer 12 (thus following a direction indicated by the arrows 13) to be assembled with the wafer 14, over a thickness ed and a width Ld. It is also possible to perform a routing or trimming in the direction indicated by the arrows 11, that meaning substantially parallel to the principal plane of the wafer 12. A routing or trimming in the two combined directions is also possible.

The width Ld is measured on a plane parallel to the mean plane of the wafer. This routing or trimming stage, performed before the assembling or transplanting stage onto the wafer 14, allows to eliminate, at least partially and from the assembly face 19 or from its lateral edges, the matter located in the peripheral zone, or located around the transplant layer 16, zone which is likely to have problems caused by the non-bonded edges.

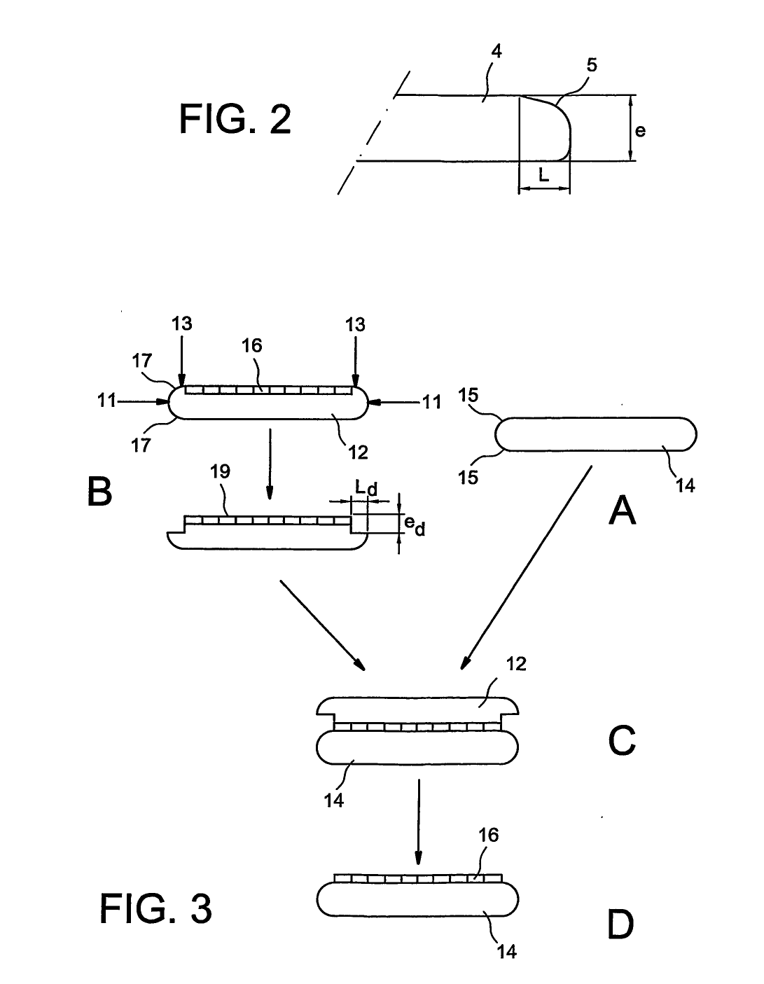

Ld is preferably greater than or equal to the width L of the rollover edge or the chamfer (FIG. 2). It can be from about a few hundred μm to a few mm, for example of between 100 μm and 5 mm.

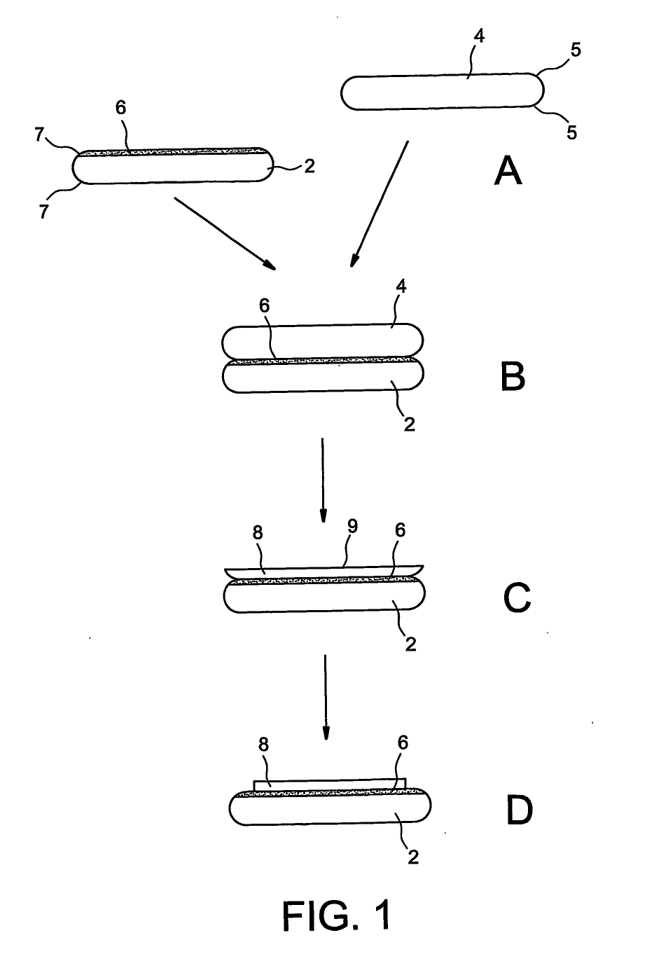

Ld is notably greater than L in the case where the non-bonding zone or zone which can not adhere to a substrate after assembling, as illustrated in stage C of FIG. 1, is itself greater than L.

Indeed, this “non-bonding” or “non-assembling” zone depends on the manner the rollover edge is made on the wafer 12 but also on the wafer 14.

It can also depend on the technical stages that could have been previously performed on the upper wafer 12 and on the support wafer 14. Regarding the width L, some stages can increase the width of this non-bonded zone (for example oxidising or depositing stages), others can reduce this said width (for example a levelling or flattening or polishing stage).

Ld can therefore be greater than or equal to the width of this non-bonding or non-assembling zone.

The thickness ed will be less than the thickness e of the wafer. It can be substantially equal to or greater or lesser than the thickness of the layer 16 (stage D, FIG. 3) or of the membrane to be obtained after the future thinning out or transplanting stage onto the wafer 14.

By way of example ed can be about a few μm or between 1 μm (or 10 μm) and 100 μm or even between 5 μm and 60 μm. As for the layer 16, it can have a thickness, for example, between 1 μm and 60 μm.

If ed is less than the thickness of the layer 16 (stage D, FIG. 3) or of the membrane to be obtained after the future thinning out or transplanting stage, then the assembling stage can be followed by an additional routing or trimming of the remaining section of substrate 12, as will be explained below.

The routing or trimming stage before assembling can be performed in a mechanical and/or chemical (notably humid) and/or mechano-chemical manner and/or via plasma. The mechanic routing can be performed for example via “edge grinding” or “edge polishing”.

It then proceeds with the assembling of the two wafers (stage C, FIG. 3) for example via molecular adhesion.

As explained above, the assembling comprises for example a surface preparation stage, a putting into contact stage and a heat treatment stage.

This heat treatment stage is performed at a few hundred degrees Celsius, for example between 100 and 1200° C., or even 1100° C., and this for a time span from a few minutes to a few hours, for example between 10 minutes and 3 hours, or even 2 hours.

Then, as illustrated in FIG. 3 (stage D), at least one of the two wafers is thinned down to the desired thickness, for example over a thickness greater than or equal to e-ed, via edge grinding and/or mechanical polishing and/or mechano-chemical polishing and/or chemical polishing. In FIG. 3 (stage D), the thinned wafer is the previously routed wafer 13.

After thinning out of the latter, a membrane made in semiconductor material, or even the layer 16 of components or circuits, thus remains bonded or assembled to the wafer 14, towards its centre. There are no lateral membranes nor any non-bonded lateral residue. The transplanting or transferring of the layer 16 is thus better than with the technology of the prior art.

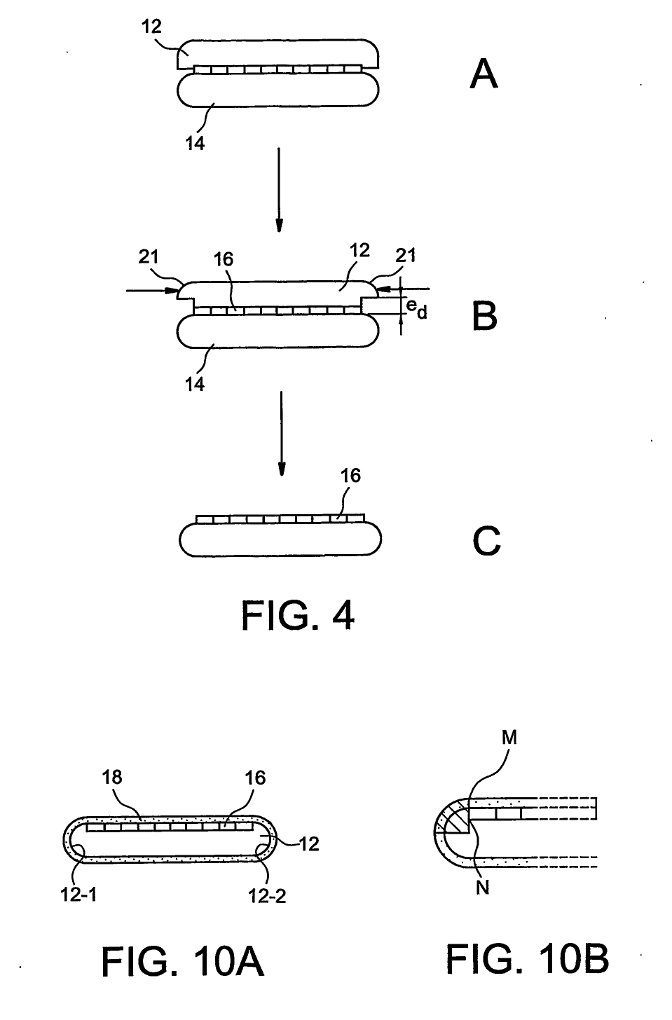

FIG. 4, part A, corresponds to the aforementioned case where the depth ed over which the wafer 12 was routed before assembling is insufficient to completely remove the layer 16 during the thinning out stage.

Assembling, which has led to the structure of FIG. 4, part A, can thus be followed with an additional routing or trimming, from the edges 13 located on the side of the front face or from the assembling face, in order to obtain a routed zone over a thickness ed greater than that of the layer 16 (FIG. 4, part B).

It is also possible to perform this additional routing or trimming from the edges 21 located on the rear face, opposite the assembling face, or even laterally, in the direction of the arrows 11 indicated in FIG. 4B.

This additional routing or trimming stage is free of the problems disclosed in the introduction to this application: there is notably no risk of spoiling or etching out the substrate 14. It can then be followed by the thinning out stage of the substrate 12, as described above (FIG. 4, part C).

Here again we obtain a transplant or a transfer free of membrane or lateral residue.

According to an alternative, the wafer 12 is completely routed over its entire thickness (FIG. 5, part A). This is the case where ed=e.

The assembling stage leads to the device represented in FIG. 5, part B, which can then be thinned out as explained above.

The wafer 12 then has a width or diameter less than that of the wafer 14.

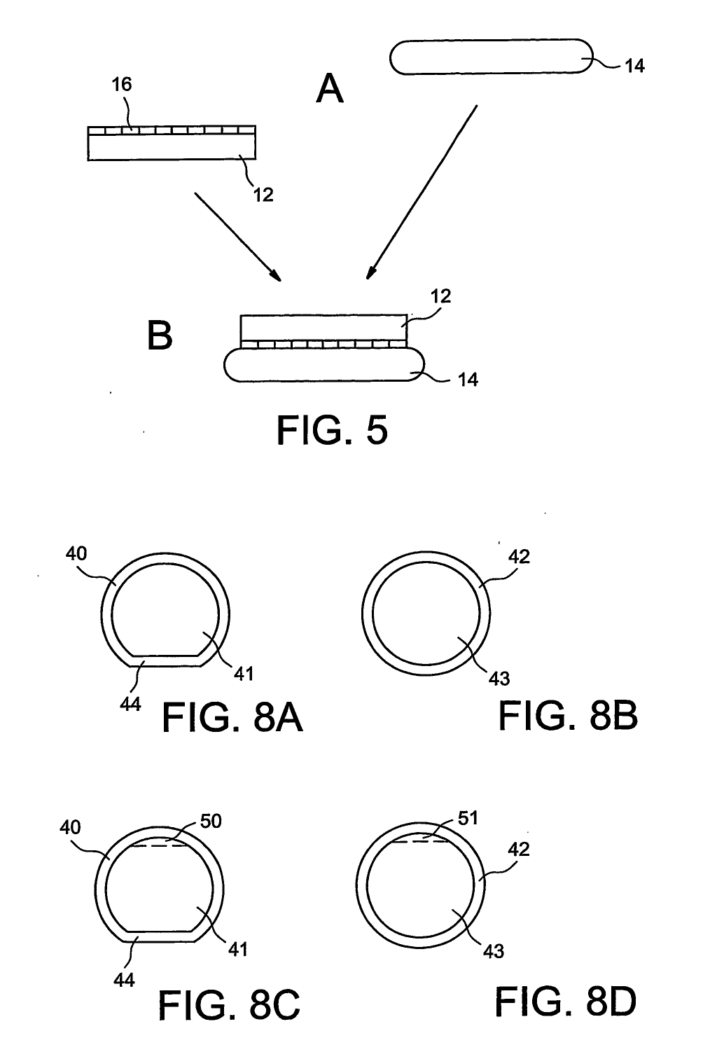

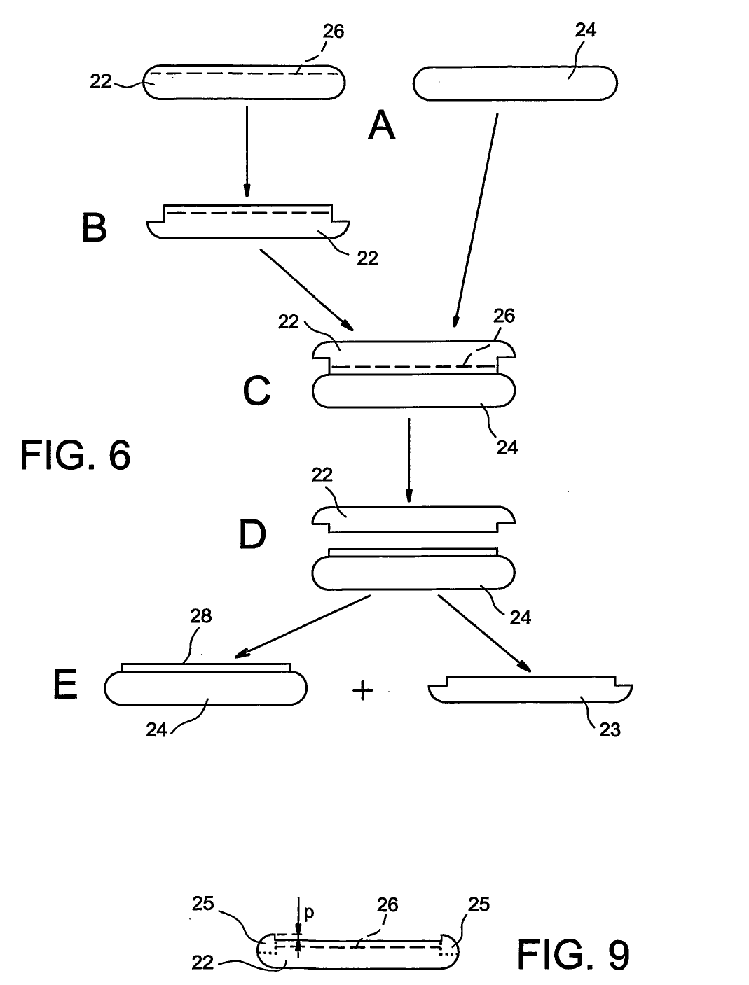

As illustrated in FIG. 6, part A, the invention also applies to an initial substrate 22 in which a weakened or fracture plane 26 was made, for example via previous ion implantation (for example a hydrogen implantation) or via creating a buried porous zone, as explained for example in the document by S. S. Iyer and al. “Silicon wafer bonding technology for VLST and MEMS applications”, published by INSPEC, 2002, Antony Rowe Ltd, or via creating a removable bonding interface.

It then proceeds with the routing or trimming of this substrate (FIG. 6, part B) over a part of its thickness or over all of its thickness, as explained above, then with the assembling of the two substrates 22 and 24.

For example, a heat treatment allows to separate the substrate 22 on the ion implantation layer 26 of hydrogen ions (FIG. 6, part D).

This results, on one hand in a unit made of the substrate 24 with a superficial layer 28 of material which comes from the initial substrate 22, and on the other hand in a substrate or a free portion 23 which also comes from the initial substrate 22 and which is reusable for subsequent operations. If the thickness over which the substrate 22 was routed or trimmed is greater than the thickness of the transplant layer 28, this substrate 22 can notably be subjected to a new ion or atom implantation, then a new transferring or transplanting stage after assembling with a new substrate 24, but without the need to perform a new routing or trimming stage.

The invention, such as is described above in connection with one of the FIGS. 3-6, also applies in the case where the initial substrate 12 and 22 has the shape illustrated in FIG. 9, with a shoulder 25 on the edges of the wafer.

These shoulders define a stiffening located at a depth P, for example lying between 50 nm and 2 μm.

The routing stage allows to remove these shoulders.

An ion implantation stage, for the creating of a weakened plane 26, can take place before or after this routing or trimming stage: a wafer is thus obtained which is identical to the one represented in part B of FIG. 6. The following stages in FIG. 6 can thus be performed as described above.

BSOI or thick SOI type structures can also be created in an efficient manner. The thinning out stage is then mechanic and/or mechano-chemical.

According to another example, electronic components are made in a wafer such as the wafer 12 (FIG. 3A) over a superficial thickness, for example, between 1 and 10 μm.

We rout or trim via “surface edge grinding” the edge of the wafer over a thickness ed of 50 μm and along a width Ld of 3 mm.

This routing stage can be performed before surface preparation (for example via mechano-chemical levelling followed by chemical cleaning) and in order to reduce the number of cleansings before assembling.

Then the routed wafer (comprising the components) is bonded via molecular adhesion onto the support wafer. The structure is then annealed for example at a temperature of 300° C. and for a time span of between a few minutes and a few hours.

The superficial wafer is then thinned out via surface edge grinding and mechano-chemical (FIG. 3, part D) and/or chemical polishing until a thickness de is obtained, for example, 10 μm.

A transplanted layer, comprising the components, transferred onto a support wafer is thus obtained.

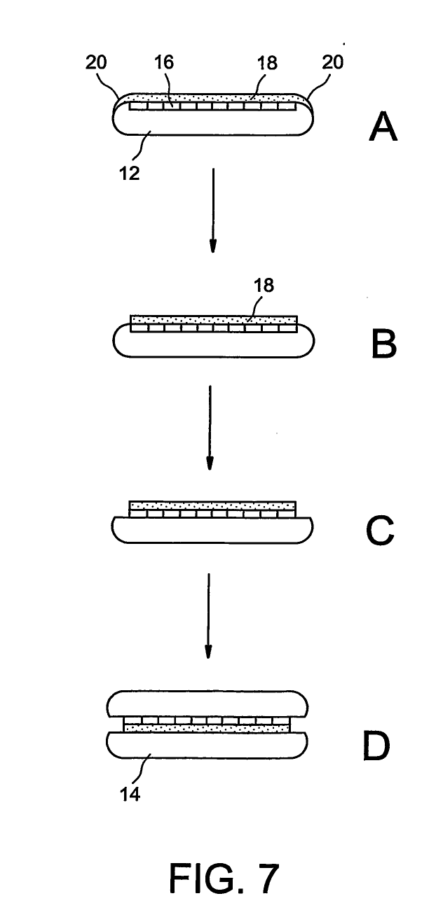

According to another embodiment, the wafer 12 comprises components 16 and is covered on its surface with a protective layer 18, for example an oxide layer 18 (FIG. 7, part A). This can also be a bonding layer.

A crown 20 is defined via lithography which will correspond to the routing zone. A local chemical etching allows to eliminate, on this zone, the protective layer 18 (FIG. 7, part B).

The edge of the substrate 12 is then etched (FIG. 7, part C), for example via chemical (ex. TMAH) or plasma etching.

The wafer is then cleaned, for example via chemical cleaning. According to an alternative, the cleaning is integrated into the chemical etching.

It can then proceed with the assembling on a wafer 14 as explained above (FIG. 7, part D).

According to an alternative in FIGS. 10A and 10B, a protective layer 18 initially coats the entire upper section of the wafer 12 as well as the edges 12-1 and 12-2, and possibly its lower section (in which case it coats the entire wafer).

The routing operation will allow to eliminate the lateral zones of this wafer such as the hatched zone in FIG. 10B. A possible scaling or clearing due to the routing operation occurs at the point M of the coating layer 18 or in a zone of this layer near this point. A scaling occurring on the wafer can generate defects, some of which can show on the surface of the wafer. A point of the surface to be assembled, such as point N, remains intact despite routing. The protective layer 18 can be eliminated after routing and before assembling.

FIGS. 8A-8D each represent a front view of a wafer 40 and 42 with a layer 41 and 43 of material around which routing was performed. This layer 41 and 43 is intended to be transplanted or transferred onto a second wafer, according to any one of the aforementioned embodiments. In FIG. 8A the wafer has a flat or a flattered zone 44.

An irregular routing can be performed, as illustrated in FIGS. 8C-8D. In these figures, the zones 50 and 51 represent zones or flats or flat surfaces which will allow to mark the support wafer. The zone 44 in FIG. 8A can also be used to mark the wafer.

Such a zone allows to provide indications regarding the nature of the wafer or an identification number of a batch to which the wafer belongs.

Irregular routing, such as in FIGS. 8A, 8C and 8D can also be performed when routing is performed after assembling, thus using the standard routing technique such as is illustrated in FIGS. 1A-1D, and possibly with one or two processed wafers, thus comprising all or part of a component or circuit. In this case, the other processing stages can be those already described above.

In particular, one of the wafers can have a chamfered edge, the routing can thus take place over a width at least equal to the width of the chamfered edge, measured on a plane parallel to that of the wafer.

The assembling can take place via molecular adhesion or via bonding.

Generally, the invention has the advantage of being able to be integrated into a method for manufacturing. This is notably the case when components are previously made in the wafers.

The invention also applies in the case of non-chamfered wafers, a stage for routing or trimming or eliminating matter in a peripheral zone of one of these two wafers being nonetheless performed before assembling the two wafers. The other processing stages are similar to those described according to one or other of the embodiments described above or below.

The method set forth in the invention is also well suited to the manufacturing of BSOI type material, or even to the transplanting of a layer of III-V material onto silicon for example.

In the case of BSOI a wafer of silicon is first oxidised in order to obtain a layer of silicon dioxide, which will serve as buried oxide.

This wafer is then routed over a 1.5 mm wide zone which corresponds to the edge or the rollover edge of the wafer, as explained above.

The surface of the wafer is then cleaned, for example via chemical and/or mechano-chemical cleaning stages.

Its surface is bonded via molecular adhesion onto a second wafer, made in silicon, and the unit is annealed at 1100° C. for 2 hours.

A surface edge grinding stage followed by a mechano-chemical polishing allows to thin the wafer down to the desired thickness in order to obtain the SOI substrate.

This said method can apply to the transplanting of III-V material such as AsGa or InP onto another material such as a semiconductor notably silicon.

This said method can also apply to the transplanting of semiconductor material such as Germanium or Germanium silicon (SiGe) onto a substrate made in another material such as a semiconductor, notably silicon.

Likewise, this method can be used to perform a transplanting of wafers of non-semiconductor material, for example wafers of insulating material such as glass or quartz, or piezoelectric material such as LiNbO3 or LiTaO3, which allows to obtain a perfectly routed thin film on a support of the same nature or of a different nature, for example a semiconductor substrate and notably silicon.

The wafers of material prepared and assembled according to the invention are wafers of “bulk” material. However, the invention applies to wafers that can contain all or part of a component, for example an electronic, and/or an electro-optic, and/or an optic, and/or a magnetic component or a MEMS.

1-37. (canceled)

38. A method for assembling a first and a second wafer, of which at least the first wafer has at least a chamfered edge, the method comprising:
covering the first wafer with a protective layer;
routing at least one part of the chamfered edge of the first wafer;
eliminating the protective layer after routing the first wafer; and
then, assembling the first wafer routed and the second wafer.

39. A method as in claim 38, further comprising, after the assembling, thinning out at least the first wafer, leaving at least a layer on the second wafer.

40. A method as in claim 38, wherein the protective layer is eliminated locally, before routing the first wafer, in a zone located above a zone to be routed of the first wafer.

41. A method as in claim 40, wherein the local elimination of the protective layer is performed via lithography and etching.

42. A method as in claim 39, wherein the routing is performed over an entire thickness of the first wafer.

43. A method as in claim 38, wherein the routing is performed over a thickness less than an entire thickness of the first wafer.

44. A method as in claim 43, wherein the routing is performed over a thickness greater than or equal to a thickness of a layer of the first wafer to be transplanted onto the second wafer.

45. A method as in claim 43, wherein the routing is performed over a thickness less than or equal to a thickness of a layer of the first wafer to be transplanted or transferred onto the second wafer.

46. A method as in claim 38, wherein the routing is performed over a width, measured on a plane parallel to that of the first wafer, at least equal to a width of the chamfered edge, measured on the same plane.

47. A method as in claim 38, further comprising an additional routing after assembling the first and second wafers.

48. A method as in claim 38, wherein the routing is performed over a thickness of the first wafer of between 1 μm and 100 μm.

49. A method as in claim 38, wherein the routing is performed over a width, measured on a plane parallel to that of the first wafer, at least equal to a width of a zone of a first wafer which can not, without routing, be assembled with the second wafer.

50. A method as in claim 38, wherein the routing is performed over a width, measured on a plane parallel to that of the first wafer, of between 100 μm and 5 mm.

51. A method as in claim 38, wherein the first wafer has a weakened plane defining a thin layer in the wafer.

52. A method as in claim 51, wherein the first wafer is routed over a thickness greater than that of the thin layer.

53. A method as in claim 52, further comprising:
thinning out via separation of the first wafer along the weakened plane, so as to leave the thin layer on the second wafer and leave a free portion of the first substrate;
creating a new weakened plane in the portion that remained free of the first substrate; and
assembling the portion with a third substrate.

54. A method as in claim 51, wherein the weakened plane is formed via ion implantation or via creating a buried porous zone or via creating a removable bonding interface.

55. A method as in claim 38, wherein the first wafer includes a lateral shoulder, eliminated during the routing.

56. A method as in claim 38, wherein the assembling the first and second wafers is performed via molecular adhesion or via bonding using an adhesive substance.

57. A method as in claim 38, wherein components or circuits are made in the first wafer before the routing.

58. A method as in claim 38, wherein the routing takes place after a previous surface preparation of the first wafer for a purpose of assembling or transplanting.

59. A method as in claim 38, wherein the routing takes place before a previous surface preparation of the first wafer for a purpose of assembling or transplanting.

60. A method as in claim 38, wherein the routing is performed via mechanical or chemical or mechano-chemical etching or polishing or via plasma etching or via a combination of at least two of these types of etching.

61. A method as in claim 38, wherein at least one of the two wafers is made in a semiconductor material.

62. A method as in claim 38, wherein at least one of the two wafers is made in silicon or in a III-V type semiconductor material.

63. A method as in claim 38, wherein at least one of the two wafers is made in Germanium or in Germanium silicide (SiGe) or in a piezoelectric material or in an insulating material.

64. A method as in claim 38, wherein the routing is performed in a regular manner around the first wafer.

65. A method as claimed in claim 38, wherein the routing is performed in an irregular manner around the first wafer, creating a plane.

66: A method as in claim 38, wherein the routing is performed in an irregular manner, creating a marking zone.

67: A method as in claim 66, further comprising marking the first wafer.

68: A method for transplanting a transplant layer of material or circuits or components, comprising:
routing a first wafer of material, in which the transplant layer is made, at least around or on a periphery of the transplant layer, over a thickness less than a thickness of the first wafer, but greater than a thickness of the transplant layer; and
transplanting the transplant layer onto a second wafer or material.

69: A method as in claim 68, wherein the first wafer previously is covered with a protective layer.

70: A method as in claim 69, wherein the protective layer is eliminated locally, before routing the first waver, in a zone located above a zone to be routed of the first wafer.

71: A method as in claim 70, wherein the local elimination of the protective layer is performed via lithography and etching.

72: A method as in claim 69, wherein the protective layer is eliminated after routing the first wafer.

73: A method as in claim 68, wherein a part of the material of the transplant layer is eliminated during the routing.

74: A method as in claim 68, wherein the first wafer is chamfered and includes at least a chamfered edge.

75: A method as in claim 74, wherein the routing is performed over a width, measured on a plane parallel to that of the first wafer, at least equal to a width of the chamfered edge, measured on the same plane.

76: A method as in claim 68, further comprising an additional routing after assembling the first and second wafers.

77: A method as in claim 68, wherein the routing is performed over a thickness of the first wafer between 1 μm and 100 μm.

78: A method as in claim 68, wherein the routing is performed over a width, measured on a plane parallel to that of the first wafer, at least equal to a width of a zone of the first wafer which can not, without routing, be assembled with the second wafer.

79: A method as in claim 68, wherein the routing is performed over a width, measured on a plane parallel to that of the first wafer of between 100 μm and 5 mm.

80: A method as in claim 38, wherein the first wafer has a weakened plane defining a thin layer in the wafer.

81: A method as in claim 80, wherein the first wafer is routed over a thickness greater than that of the thin layer.

82: A method as in claim 81, further comprising:
thinning out, via separation of the first wafer along the weakened plane, so as to leave the thin layer on the second wafer and leave a free portion of the first substrate;
creating a new weakened plane in the portion that remained free of the first substrate; and
assembling the portion with a third substrate.

83: A method as in claim 81, wherein the weakened plane is performed via ion implantation or via creating a buried porous zone or via creating a removable bonding interface.

84: A method as in claim 38, wherein the first wafer includes a lateral shoulder, eliminated during the routing.

85: A method as in claim 68, wherein the assembling the first and second wafers is performed via molecular adhesion or via bonding using an adhesive substance.

86: A method as in claim 68, wherein components or circuits are made in the first wafer before the routing.

87: A method as in claim 68, wherein the routing takes place after a previous surface preparation of the first wafer for a purpose of assembling or transplanting.

88: A method as in claim 68, wherein the routing takes place before a previous surface penetration of the first wafer for a purpose of assembling or transplanting.

89: A method as in claim 68, wherein the routing is performed via mechanical or chemical or mechano-chemical etching or polishing or via plasma etching or via a combination of at least two of these types of etching.

90: A method as in claim 68, wherein at least one of the two wafers is made in a semiconductor material.

91: A method as in claim 68, wherein at least one of the two wafers is made in silicon or in a III-V type semiconductor material.

92: A method as in claim 68, wherein at least one of the two wafers is made in Germanium or in Germanium silicide (SiGe) or in a piezoelectric material or in an insulating material.

93: A method as in claim 68, wherein the routing is performed in a regular manner around the first wafer.

94: A method as in claim 68, wherein the routing is performed in an irregular manner around the first wafer, creating a plane.

95: A method as in claim 68, wherein the routing is performed in an irregular manner, creating a marking zone.

96: A method as in claim 95, further comprising marking the first wafer.

97: A method for assembling a first and a second wafer, of which at least the first wafer has at least a chamfered edge, the method comprising:
covering the first wafer with a protective layer;
routing at least one part of the chamfered edge of the first wafer and of the protective layer, in a zone located above a zone of the first wafer to be routed;
eliminating the protective layer after routing the first wafer; and
then, assembling the first wafer routed and the second wafer.
